(19) United States
(12) Patent Application Publication
(10) Pub. No.: US 2013/0161732 A1
(43) Pub. Date: Jun. 27, 2013

(54) VERTICAL CHANNEL THIN FILM TRANSISTOR

(71) Applicant: Electronics and Telecommunications Research Institute, Daejeon (KR)

(72) Inventors: Chi Sun HWANG, Daejeon (KR); Sang Hee Park, Daejeon (KR)

(73) Assignee: Electronics and Telecommunications Research Institute, Daejeon (KR)

(21) Appl. No.: 13/712,428

(22) Filed: Dec. 12, 2012

(30) Foreign Application Priority Data
Dec. 27, 2011 (KR) 10-2011-0143098

(51) Int. Cl. H01L 29/78

(52) U.S. Cl. CPC H01L 29/7827
USPC 257/329

(57) ABSTRACT

Disclosed is a vertical channel thin film transistor including a substrate; a drain electrode formed on the substrate; a spacer formed on the substrate while coming into contact with the drain electrode; a source electrode formed on the spacer; an active layer formed on an entire surface of the substrate including the drain electrode and the source electrode and configured to form a vertical channel; a gate insulating layer formed on the active layer; and a gate electrode formed on the gate insulating layer.

### CROSS-REFERENCE TO RELATED APPLICATIONS

This application is based on and claims priority from Korean Patent Application No. 10-2011-0143098, filed on Dec. 27, 2011, with the Korean Intellectual Property Office, the disclosure of which is incorporated herein in its entirety by reference.

### TECHNICAL FIELD

The present disclosure relates to a thin film transistor, and more particularly, to a thin film transistor having a channel perpendicular to a substrate.

### BACKGROUND

A thin film transistor (TFT) based on a thin film deposition technique has been extensively developed while being mainly used as a backplane device of a flat display. Recently, an oxide semiconductor thin film transistor using a metal oxide semiconductor has received a lot of attention.

According to the development of the thin film transistor, an application range thereof has become wider, and thus, a need to develop a thin film transistor operating with a low voltage has increased. In such a process, there is an attempt to implement the low voltage driving by adopting a vertical channel and making a length of the channel very short.

FIG. 1 is a cross-sectional view illustrating a structure of a vertical channel thin film transistor in the related art.

Referring to FIG. 1, the vertical channel thin film transistor in the related art includes a substrate 110, a drain electrode 120 formed on the substrate 110, a first spacer 130 formed on the drain electrode 120, a source electrode 140 formed on the first spacer 130, a second spacer 150 formed on the source electrode 140, an active layer 160 formed on an entire surface of the substrate 110 including the second spacer 150 and configured to form a vertical channel between the source electrode 140 and the drain electrode 120, a gate insulating layer 170 formed on the active layer 160, and a gate electrode 180 formed on the gate insulating layer 170.

In general, since the thin film transistor is considered to be applied to a large size device, it is not easy to implement a short channel by using a photolithography process used in the MOSFET. However, if the method as illustrated in FIG. 1 is used, since a distance between the source electrode 140 and the drain electrode 120 is determined by a thickness of the first spacer 130, it is possible to define a very short channel length.

Meanwhile, in FIG. 1, a contact area between the active layer 160 and the source/drain electrodes 140 and 120 is defined by multiplying a thickness of the source/drain electrodes 140 and 120 and an area of a pattern of the source/drain electrodes 140 and 120. The contact area is reduced to from ⅓ to 1/20 of the contact area of the general thin film transistor having a contact area of several um². In general, when it is considered that contact resistance is reversely proportional to the contact area, the contact resistance is increased 3 to 20 times more through a simple calculation, and the increase in the contact resistance directly results in a decrease in a driving current of the thin film transistor. If a current crowding phenomenon is generated due to the decrease in the contact area, contact resistance may be further increased.

### SUMMARY

The present disclosure has been made in an effort to provide a vertical channel thin film transistor for reducing contact resistance generated due to a very narrow contact area between an active layer and source/drain electrodes.

An exemplary embodiment of the present disclosure provides a vertical channel thin film transistor including: a substrate; a drain electrode formed on the substrate; a spacer formed on the substrate while coming into contact with the drain electrode; a source electrode formed on the spacer; an active layer formed on an entire surface of the substrate including the drain electrode and the source electrode and configured to form a vertical channel; a gate insulating layer formed on the active layer; and a gate electrode formed on the gate insulating layer.

According to the exemplary embodiments of the present disclosure, by providing a vertical channel thin film transistor in which contact between an active layer and source/drain electrodes is achieved on a flat surface, it is possible to sufficiently secure a contact area of several um² according to a pattern length, and thus prevent contact resistance from being increased through a decrease in the contact area.

According to the exemplary embodiments of the present disclosure, it is possible to minimize generation of a leakage current and capacitance by providing a vertical channel thin film transistor in which the overlapping area between a source electrode and a drain electrode is minimized

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a cross-sectional view illustrating a structure of a vertical channel thin film transistor in the related art.

FIG. 2 is a cross-sectional view illustrating a structure of a vertical channel thin film transistor according to an exemplary embodiment of the present disclosure.

FIGS. 3A to 3C are processes illustrating a method of manufacturing a vertical channel thin film transistor according to an exemplary embodiment of the present disclosure.

### DETAILED DESCRIPTION

In the following detailed description, reference is made to the accompanying drawing, which form a part hereof. The illustrative embodiments described in the detailed description, drawing, and claims are not meant to be limiting. Other embodiments may be utilized, and other changes may be made, without departing from the spirit or scope of the subject matter presented here.

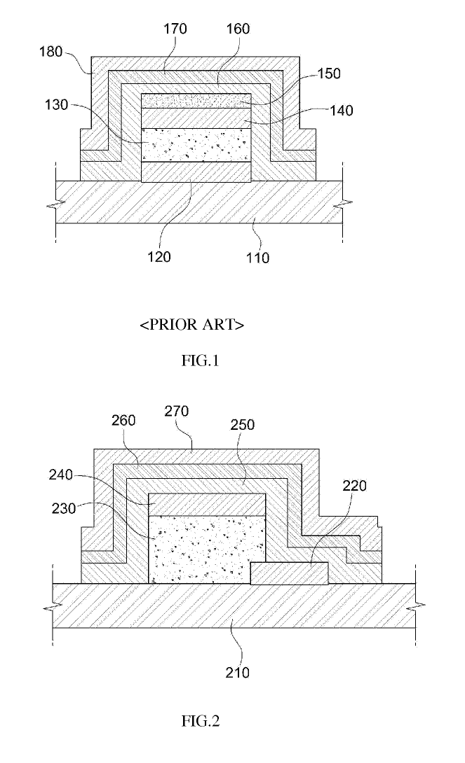

FIG. 2 is a cross-sectional view illustrating a structure of a vertical channel thin film transistor according to an exemplary embodiment of the present disclosure.

Referring to FIG. 2, the vertical channel thin film transistor according to the present disclosure includes a substrate 210, a drain electrode 220 formed on the substrate 210, a spacer 230 formed on the substrate 210 while coming into contact with the drain electrode 220, a source electrode 240 formed on the spacer 230, an active layer 250 formed on an entire surface of the substrate 210 including the drain electrode 220 and the source electrode 240 and configured to form a vertical channel, a gate insulating layer 260 formed on the active layer 250, and a gate electrode 270 formed on the gate insulating layer 260. Here, the drain electrode 220 and the source electrode 240 partially overlap each other with the spacer 230 therebetween. At this time, the spacer 230 may be thicker than the drain electrode 220 so that the drain electrode 220 and the source electrode 240 do not come into contact with each other.

As described above, the vertical channel thin film transistor according to the present disclosure can sufficiently secure a contact area of several um² according to a pattern length since contact between the active layer 250 and the source/drain electrodes 240 and 220 is achieved on a flat surface instead of at a cross section, and thus it is possible to prevent the contract resistance from being increased through a decrease in the contract area.

As illustrated in FIG. 1, when the contact between the source/drain electrodes 140 and 120 and the active layer 160 is achieved on the cross section, since the contact area is an etching cross section, there is a possibility that a foreign material or a damaged layer by a process effect exists on the contact area, but the vertical channel thin film transistor according to the present disclosure can exclude the possibility.

In the structure of the vertical channel thin film transistor illustrated in FIG. 1, since an overlapping area between the source electrode 140 and the drain electrode 120 is very wide, if there is the first spacer 130 having a thin thickness between the two electrodes, a leakage current or very large parasitic capacitance may be generated.

However, in the vertical channel thin film transistor according to the present disclosure, it is possible to minimize the generation of the leakage current and the capacitance by minimizing the overlapping area between the source electrode 240 and the drain electrode 220.

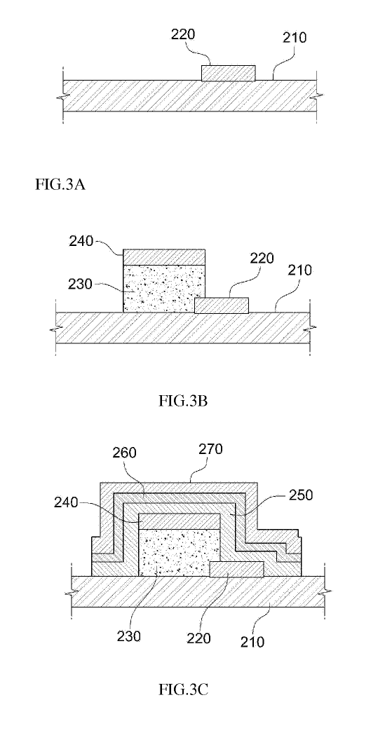

FIGS. 3A to 3C are processes illustrating a method of manufacturing a vertical channel thin film transistor according to an exemplary embodiment of the present disclosure.

As illustrated in FIG. 3A, a source/drain metal layer is deposited on the substrate 210 by a deposition method such as sputtering. Subsequently, the drain electrode 220 is formed by patterning the source/drain metal layer through a photolithography process and an etching process using a first mask. Here, the source/drain metal layer may include molybdenum (Mo), titanium, tantalum, and a molybdenum alloy (Mo Alloy).

As illustrated in FIG. 3B, an insulating layer and the source/drain metal layer are sequentially deposited on the substrate 210 on which the drain electrode 220 is formed. Subsequently, the spacer 230 and the source electrode 240 are formed by patterning the insulating layer and the source/drain metal layer through a photolithography process and an etching process using a second mask. At this time, the drain electrode 220 and the source electrode 240 may be formed to have the spacer 230 therebetween such that an overlapping part is minimized or removed. The spacer 230 may be formed to be thicker than the drain electrode 220 so that the drain electrode 220 and the source electrode 240 do not meet.

As illustrated in FIG. 3C, a semiconductor layer, an insulating layer, and a gate metal layer are sequentially deposited on the substrate 210 on which the drain electrode 220, the spacer 230, and the source electrode 240 are formed. Subsequently, the active layer 250, the gate insulating layer 260, and the gate electrode 270 are formed by patterning the semiconductor layer, the insulating layer, and the gate metal layer through a photolithography process and an etching process using a third mask. Here, the gate metal layer may have a single layer structure or a dual-layer structure including chromium (Cr), molybdenum (Mo) and an aluminum based metal. At this time, the semiconductor layer, the insulating layer, and the gate metal layer may be deposited using an atomic layer deposition method having excellent step coverage in order to easily form a thin film on a vertical surface.

From the foregoing, it will be appreciated that various embodiments of the present disclosure have been described herein for purposes of illustration, and that various modifications may be made without departing from the scope and spirit of the present disclosure. Accordingly, the various embodiments disclosed herein are not intended to be limiting, with the true scope and spirit being indicated by the following claims.

What is claimed is:

1. A vertical channel thin film transistor, comprising:
a substrate;
a drain electrode formed on the substrate;
a spacer formed on the substrate while coming into contact with the drain electrode;
a source electrode formed on the spacer;
an active layer formed on an entire surface of the substrate including the drain electrode and the source electrode and configured to form a vertical channel;
a gate insulating layer formed on the active layer; and
a gate electrode formed on the gate insulating layer.

2. The vertical channel thin film transistor of claim 1, wherein the drain electrode and the source electrode partially overlap each other with the spacer therebetween.

3. The vertical channel thin film transistor of claim 1, wherein the spacer is thicker than the drain electrode.

4. The vertical channel thin film transistor of claim 1, wherein the drain electrode and the source electrode do not overlap each other with the spacer therebetween.
